(19) United States
(12) Patent Application Publication
(10) Pub. No.: US 2019/0203343 A1
(43) Pub. Date: Jul. 4, 2019

(54) EVAPORATION SOURCE AND VAPOR DEPOSITION APPARATUS

(71) Applicant: SHENZHEN CHINA STAR OPTOELECTRONICS SEMICONDUCTOR DISPLAY TECHNOLOGY CO., LTD., Shenzhen (CN)

(72) Inventors: Aiguo TU, Shenzhen (CN); Jinchuan LI, Shenzhen (CN)

(21) Appl. No.: 16/058,012

(22) Filed: Aug. 8, 2018

Related U.S. Application Data
(63) Continuation of application No. PCT/CN2018/072734, filed on Jan. 15, 2018.

(30) Foreign Application Priority Data
Dec. 28, 2017 (CN) 201711462654.6

(51) Int. Cl. C23C 14/24; H01L 51/00; H01L 51/56

(52) U.S. Cl. CPC C23C 14/24; H01L 51/56; H01L 51/0011; H01L 51/001

(57) ABSTRACT

The present application provides an evaporation source, including a cavity and a nozzle. The cavity includes a top and a bottom opposite to each other, the nozzle is disposed on the top wall of the cavity and connected to a draft tube, a fixing device is disposed on the side wall of the cavity, the draft tube is bent through the top of the cavity and fixed to the side wall surface of the cavity by the fixing device. The draft tube is fixed on the side wall surface of the cavity by the fixing device, when the draft tube leaves the evaporation source, it also passes through the relatively high temperature area of the side wall surface of the cavity, the temperature drop of the draft tube slows down so that the temperature in the pipeline is high. The present application also provides a vapor deposition apparatus.

### RELATED APPLICATIONS

This application is a continuation application of PCT Patent Application No. PCT/CN2018/072734, filed Jan. 15, 2018, and claims the priority of China Application CN 201711462654.6, filed Dec. 28, 2017, which is herein incorporated by reference in its entirety.

### FIELD OF THE DISCLOSURE

The present disclosure relates to a vapor deposition technology field, and more particularly to an evaporation source and a vapor deposition apparatus.

### BACKGROUND OF THE DISCLOSURE

Vapor deposition method is a physical vapor deposition of vacuum coating technology. It is the vapor deposition material is placed in an evaporation source, by heating the evaporation source, the material from the solid state into gaseous atoms, radicals or molecules, and then deposited on the substrate surface to be coated to form a thin film.

OLED display technology, the general use of vacuum thermal evaporation of organic materials, organic materials by adding the evaporation source, the vacuum environment by heating the organic material or metal material to reach the evaporation temperature, so that the material evaporated or sublimated onto the substrate film made OLED display device.

The existing Fine Metal Mask (FMM) technology corresponds to the largest substrate size is 1500*92.5 cm, has been used mass production of AMOLED small and medium size, but the Fine Metal Mask (FMM) is difficult for large-size AMOLED production.

The Organic Vapor Phase Deposition (OVPD) process has been commercialized and uses the principle of inert carrier gas for transportation to control small molecule condensation. However, due to the long distance from the evaporation source to the shower head or the sprinkler, organic vapor phase deposition tends to form agglomeration in the pipeline, and the agglomerated steam molecules are easily brought to the substrate by the carrier gas to cause defects.

### SUMMARY OF THE DISCLOSURE

The purpose of the present application is to provide an evaporation source, which solves the problem that the existing draft tube has a long distance and leads to poor performance.

For the purpose of the present application, the present application provides the following technical solutions.

According to a first aspect, an evaporation source, including a cavity and a nozzle, wherein the cavity includes a top and a bottom opposite to each other, the nozzle is disposed on the top wall of the cavity and connected to a draft tube, a fixing device is disposed on the side wall of the cavity, the draft tube is bent through the top of the cavity and fixed to the side wall surface of the cavity by the fixing device.

In a first possible implementation manner of the first aspect, the fixing device includes a first fixing plate, the first fixing plate is provided with a through hole downward from the top of the cavity, and the draft tube is inserted through the through hole.

In a second possible implementation manner of the first aspect, the fixing device includes a second fixing plate, a groove downward from the top of the cavity is provided on the side of the second fixing plate opposite to the side wall of the cavity, the draft tube is disposed in the groove.

In a third possible implementation manner of the first aspect, the fixing device includes at least two stoppers, an interval between two adjacent stoppers forms a downward gap from the top of the cavity, the draft tube is received in the gap.

With reference to the first aspect and the first to the third possible implementation manners of the first aspect, in a fourth possible implementation manner of the first aspect, the fixing device is provided with more than two layers on the side wall surface of the cavity, the two or more fixing devices have the same structure, and the projections downward from the top of the cavity are the same.

With reference to the first aspect and the first to the third possible implementation manners of the first aspect, in a fifth possible implementation manner of the first aspect, the height of the fixing device on the side wall of the cavity is the same as the height of the cavity, and the opposite upper portion of the fixing device is aligned with the top of the cavity.

In a sixth possible implementation manner of the first aspect, the draft tube and the nozzle are connected with each other by a bolt and a copper seal ring.

In a seventh possible implementation manner of the first aspect, a steam dispersing plate is also disposed in the cavity, and the steam dispersing plate is configured to uniformly disperse the steam so as to obtain a uniform steam flow rate.

In an eighth possible implementation manner of the first aspect, the cavity is provided with a feeding port opposite to the adjacent side of the fixing device.

The present application also provides a vapor deposition apparatus, which includes the evaporation source in the foregoing various implementations.

Beneficial effects of the present application:

in the evaporation source provided by the present application, the draft tube is fixed on the side wall surface of the cavity by the fixing device, when the draft tube leaves the evaporation source, it also passes through the relatively high temperature area of the side wall surface of the cavity, the temperature drop of the draft tube slows down so that the temperature in the pipeline is high, the vaporized small molecules of vapor are not easily condensed in the draft tube to prevent the occurrence of substrate defects.

### BRIEF DESCRIPTION OF THE DRAWINGS

To describe the technical solutions in the embodiments of the present application or in the prior art more clearly, the following briefly introduces the accompanying drawings required for describing the embodiments or the prior art. Apparently, the accompanying drawings in the following description show merely some embodiments of the application, and a person of ordinary skill in the art may still derive other drawings from these accompanying drawings without creative efforts.

FIG. 1 is a schematic structural diagram of the vapor deposition apparatus according to the embodiment of the present application.

FIG. 2 is a schematic front view of the embodiment of the evaporation source in FIG. 1.

FIG. 3 is a schematic bottom view of the embodiment of the evaporation source in FIG. 2.

FIG. 4 is a schematic structural diagram of another embodiment of the evaporation source in FIG. 2.

FIG. 5 is a schematic structural diagram of another embodiment of the evaporation source in FIG. 2.

FIG. 6 is a schematic left side view of the embodiment of the evaporation source in FIG. 2.

FIG. 7 is a schematic left side view of another embodiment of the evaporation source in FIG. 2.

### DETAILED DESCRIPTION OF PREFERRED EMBODIMENTS

The technical solutions in the embodiments of the present application are clearly and completely described below with reference to the accompanying drawings in the embodiments of the present application. Apparently, the described embodiments are merely some but not all of the embodiments of the present application. All other embodiments obtained by a person of ordinary skill in the art based on the embodiments of the present application without creative efforts shall fall in the protection scope of this application.

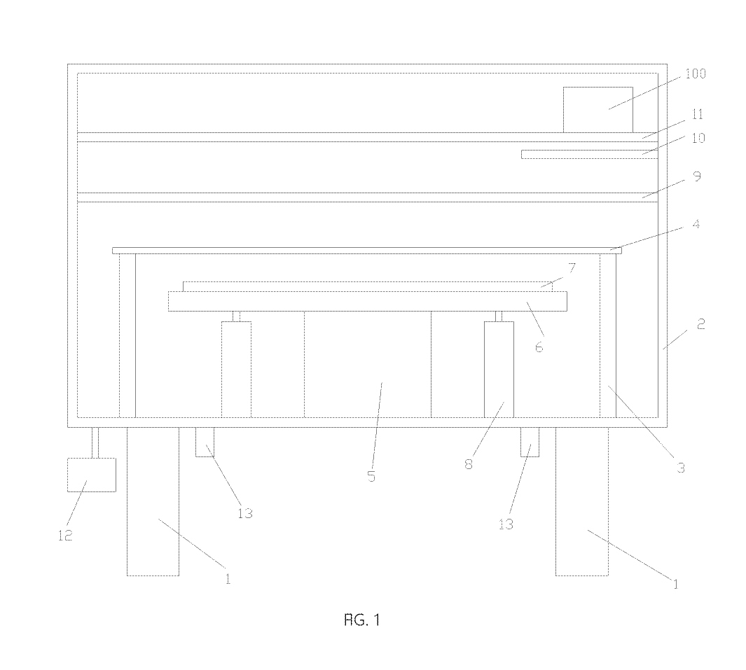

Please refer to FIG. 1, which is a schematic structural diagram of a vapor deposition apparatus to which the evaporation source in the embodiment of the present application is applied. The vapor deposition apparatus includes a vacuum pump 12, a reticle stage 3, a substrate stage 6, an evaporation source 100, an evaporation source baffle 10, a main baffle 9. The substrate stage 6 further includes an alignment platform 8 for adjusting the position of the substrate 7 on a plane. After the alignment, the substrate stage 6 is moved upward, the substrate 7 and the mask 4 are bonded together, and then the film is deposited by evaporation. The vapor deposition apparatus also includes a cavity base 1, an alignment camera 13, a lifting mechanism 5 of the substrate stage, an evaporation source moving rail 11 and the like. The specific structure of the evaporation source 100 and the components such as the draft tube are omitted in the figure.

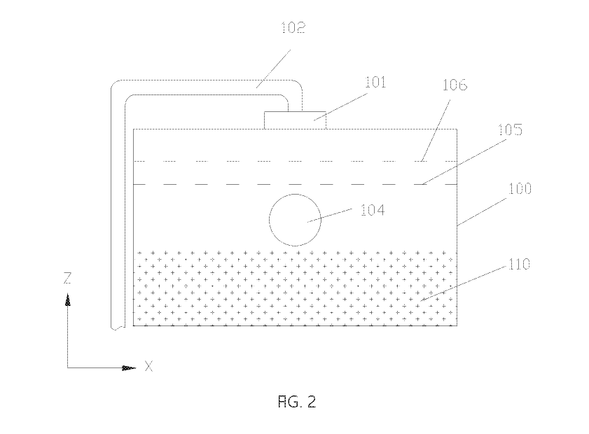

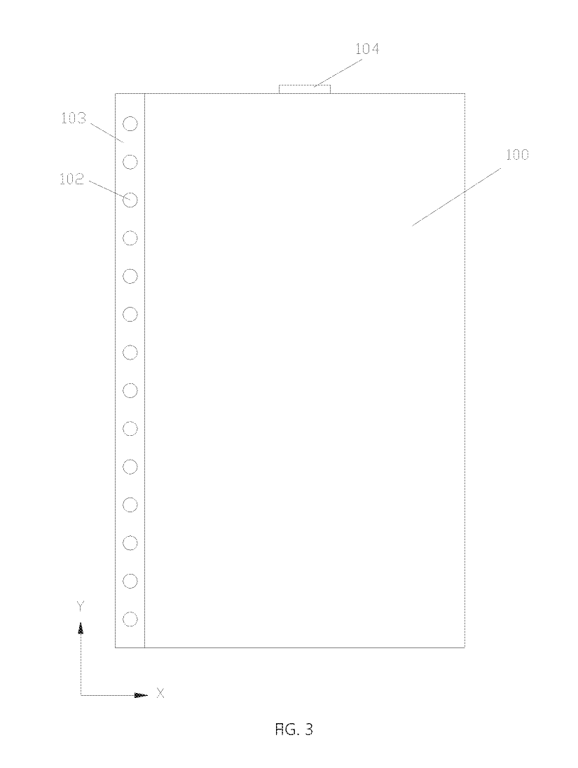

Referring to FIG. 2, a preferred embodiment of the present application provides an evaporation source, including a cavity 100 and a nozzle 101. The cavity 100 includes an opposite top and a bottom. The nozzle 101 is disposed on the top wall of the cavity 100. The nozzle 101 is connected to the draft tube 102. The side wall of the cavity 100 is provided with a fixing device (not shown in FIG. 2, reference may be made to 103 in FIG. 3 to FIG. 6). The draft tube 102 is bent at the top of the cavity 100 and fixed to the side wall surface of the cavity 100 by the fixing device.

In the present embodiment, the draft tube 102 is fixed to the side wall surface of the cavity 100 by the fixing device. When the draft tube 102 leaves the evaporation source, it also passes through the relatively high temperature region of the side wall of the cavity 100 to slow down the temperature drop of the draft tube 102 so that the temperature in the pipeline is high. The steam for evaporation of small molecules in the diversion duct is not easy to aggregate, to prevent substrate defects.

In the present embodiment, the cavity 100 is made of a metal material and has good thermal conductivity on the side wall thereof. The shape of the cavity is a cylinder or a cube, in which a closed cavity is formed for accommodating the evaporation material 110. The side wall of the cavity is a flat surface or a curved surface with a straight line from the top of the cavity to the bottom of the cavity, so that the draft tube 102 can abut on the side wall of the cavity to a maximum extent to ensure the thermal insulation effect of the cavity on the draft tube.

In the present embodiment, the draft tube 102 is in close contact with the side wall surface of the cavity 100. Of course, in other embodiments, the draft tube 102 may have a certain gap with the side wall surface. For example, the gap may be 1 mm to 10 mm. The fixing device may be made of metal or non-metallic material with good thermal conductivity. The fixing device may be fixedly connected with the side wall of the cavity 100 or may be detachably connected.

In the present embodiment, a bolt and a copper sealing ring (not shown) are connected between the draft tube 102 and the nozzle 101 to prevent steam leakage. A plurality of nozzles 101 may be disposed on the cavity 100, corresponding to a plurality of draft tubes 102, vapor deposition efficiency can be improved, and production efficiency can be improved. At least one steam dispersing plate 105 (106) is also disposed in the cavity 100 for uniformly dispersing the steam to obtain a uniform steam flow rate. The cavity 100 is provided with a feeding port 104 opposite to the adjacent side of the fixing device for replenishing the evaporation material. Understandably, the cavity may also be provided with inspection openings (not shown), for inspection and repair workers or equipment to enter.

In an implementation manner, referring to FIG. 3, the fixing device includes a first fixing plate 103. A through hole (indicated by 102) downward from the top of the cavity 100 is defined in the fixing plate 103. The guiding tube 102 penetrates through the through hole. The draft tube 102 is surrounded by the inner wall surface of the through hole so that the ambient temperature of the draft tube 102 is relatively high so as to facilitate the transportation of steam and prevent the vapor molecules from being agglomerated easily.

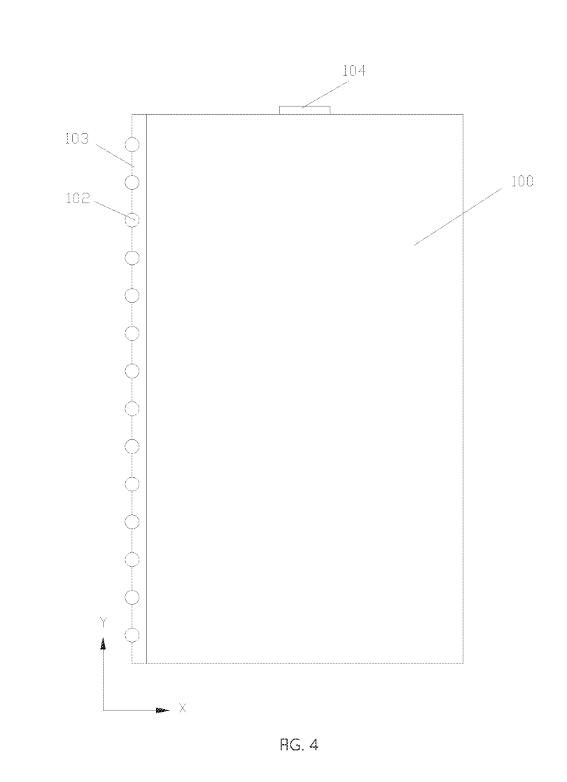

In an implementation manner, referring to FIG. 4, the fixing device includes a second fixing plate 103. A groove (102) downwardly extending from the top of the cavity 100 is defined in the side of the second fixing plate 103 facing away from the side wall of the cavity 100. The draft tube 102 is disposed in the groove. According to the shape of the draft tube 102, the flute is generally arc-shaped. By providing the groove, the thermal insulation effect on the draft tube can be achieved, and the groove processing is more convenient than the solution of the through hole.

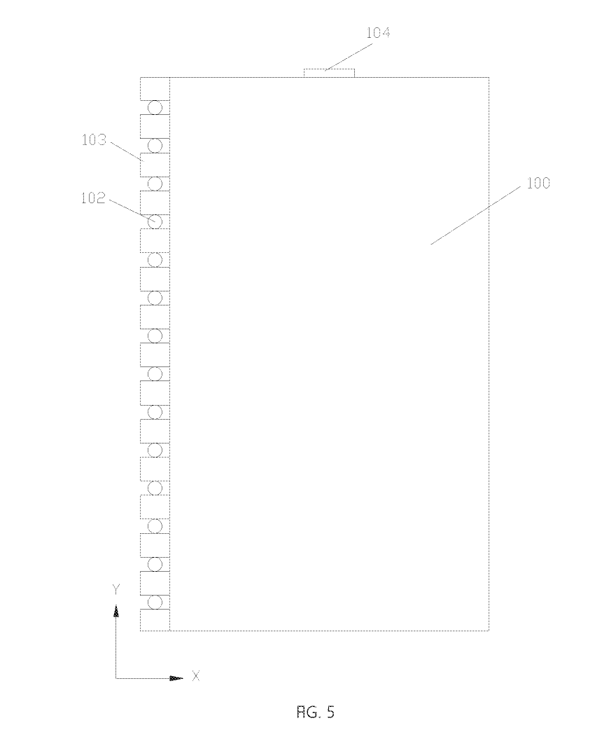

In an implementation manner, referring to FIG. 5, the fixing device includes a stopper 103, which includes at least two stoppers 103. A gap is formed between two adjacent stoppers 103 downward from the top of the cavity 100, the draft tube 102 is received in the gap. The stoppers can be regular rectangular stoppers and can also be adapted to the shape of the draft tube 102 to more surround the outer surface of the draft tube 102. Compared with the through hole and the groove of the program, the stopper for the parts, according to different specifications of the catheter set. For example, when the diameter of the draft tube 102 is changed, the gap between adjacent stoppers can be slightly adjusted to accommodate, while the through holes and recesses need to be replaced.

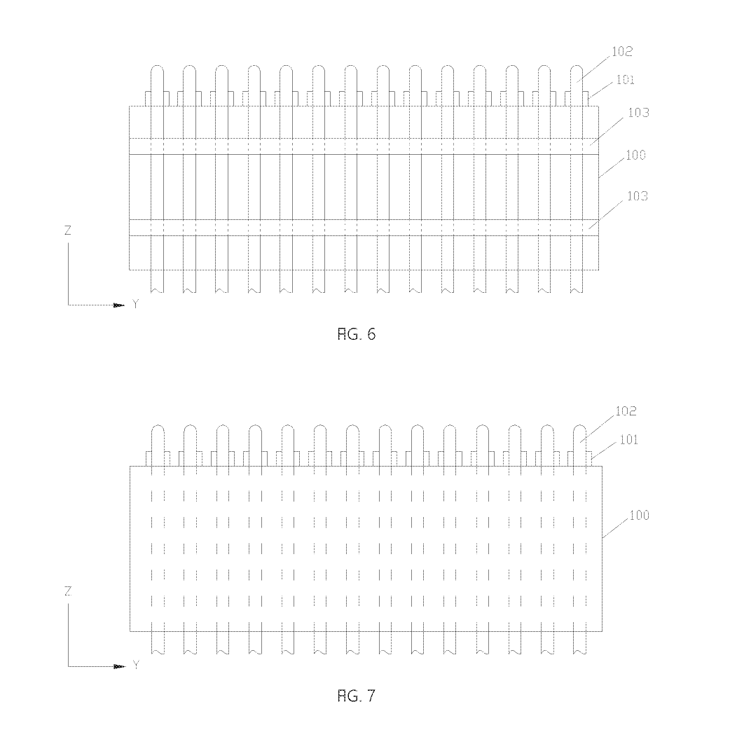

In an implementation manner, referring to FIG. 6, the fixing device 103 is provided with two or more layers on the side wall of the cavity 100. The two or more fixing devices 103 have the same structure, and the projections downward from the top of the cavity are the same. By providing the same fixing device 103 and having the same projection, the flow direction of the draft tube 102 on the side wall surface of the cavity can be made straight, so as to avoid the excess bending caused by the extension of the pipeline and cause the aggregation phenomenon.

In an implementation manner, referring to FIG. 7, the height of the fixing device on the side wall of the cavity 100 is the same as the height of the cavity 100, and the opposite upper portion of the fixing device is aligned with the top of the cavity 100. Further, the fixing device is integrally formed with the cavity 100 and can be manufactured together with the cavity 100. For example, a casting process and a machining process are available.

The above disclosure is only one preferred implementation of the present application, and certainly can not be used to limit the scope of the present application. Those of ordinary skill in the art can understand that all or part of the processes for implementing the foregoing embodiments and equivalent changes made according to the claims of the present application still fall within the scope of the application.

What is claimed is:

1. An evaporation source, comprising a cavity and a nozzle, wherein the cavity comprises a top and a bottom opposite to each other, the nozzle is disposed on a top wall of the cavity and connected to a draft tube, a fixing device is disposed on a side wall of the cavity, the draft tube is bent through the top of the cavity and fixed to a side wall surface of the cavity by the fixing device.

2. The evaporation source according to claim 1, wherein the fixing device comprises a first fixing plate, the first fixing plate is provided with a through hole downward from the top of the cavity, and the draft tube is inserted through the through hole.

3. The evaporation source according to claim 1, wherein the fixing device comprises a second fixing plate, a groove downward from the top of the cavity is provided on a side of the second fixing plate opposite to the side wall of the cavity, the draft tube is disposed in the groove.

4. The evaporation source according to claim 1, wherein the fixing device comprises at least two stoppers, an interval between two adjacent stoppers forms a downward gap from the top of the cavity, the draft tube is received in the gap.

5. The evaporation source according to claim 2, wherein the fixing device is provided with more than two layers on the side wall surface of the cavity, the two or more fixing devices have a same structure, and projections downward from the top of the cavity are the same.

6. The evaporation source according to claim 3, wherein the fixing device is provided with more than two layers on the side wall surface of the cavity, the two or more fixing devices have a same structure, and projections downward from the top of the cavity are the same.

7. The evaporation source according to claim 4, wherein the fixing device is provided with more than two layers on the side wall surface of the cavity, the two or more fixing devices have a same structure, and projections downward from the top of the cavity are the same.

8. The evaporation source according to claim 2, wherein a height of the fixing device on the side wall of the cavity is the same as a height of the cavity, and an opposite upper portion of the fixing device is aligned with the top of the cavity.

9. The evaporation source according to claim 3, wherein a height of the fixing device on the side wall of the cavity is the same as a height of the cavity, and an opposite upper portion of the fixing device is aligned with the top of the cavity.

10. The evaporation source according to claim 4, wherein a height of the fixing device on the side wall of the cavity is the same as a height of the cavity, and an opposite upper portion of the fixing device is aligned with the top of the cavity.

11. The evaporation source according to claim 1, wherein the draft tube and the nozzle are connected with each other by a bolt and a copper seal ring.

12. The evaporation source according to claim 1, wherein a steam dispersing plate is also disposed in the cavity, and the steam dispersing plate is configured to uniformly disperse a steam so as to obtain a uniform steam flow rate.

13. The evaporation source according to claim 1, wherein the cavity is provided with a feeding port opposite to an adjacent side of the fixing device.

14. A vapor deposition apparatus, comprising a cavity and a nozzle, wherein the cavity comprises a top and a bottom opposite to each other, the nozzle is disposed on a top wall of the cavity and connected to a draft tube, a fixing device is disposed on a side wall of the cavity, the draft tube is bent through the top of the cavity and fixed to a side wall surface of the cavity by the fixing device.

15. The vapor deposition apparatus according to claim 14, wherein the fixing device comprises a first fixing plate, the first fixing plate is provided with a through hole downward from the top of the cavity, and the draft tube is inserted through the through hole.

16. The vapor deposition apparatus according to claim 14, wherein the fixing device comprises a second fixing plate, a groove downward from the top of the cavity is provided on a side of the second fixing plate opposite to the side wall of the cavity, the draft tube is disposed in the groove.

17. The vapor deposition apparatus according to claim 14, wherein the fixing device comprises at least two stoppers, an interval between two adjacent stoppers forms a downward gap from the top of the cavity, the draft tube is received in the gap.

18. The vapor deposition apparatus according to claim 15, wherein the fixing device is provided with more than two layers on the side wall surface of the cavity, the two or more fixing devices have a same structure, and projections downward from the top of the cavity are the same.

19. The vapor deposition apparatus according to claim 15, wherein a height of the fixing device on the side wall of the cavity is the same as a height of the cavity, and an opposite upper portion of the fixing device is aligned with the top of the cavity.

20. The vapor deposition apparatus according to claim 14, wherein the draft tube and the nozzle are connected with each other by a bolt and a copper seal ring.
